(19) United States
(12) Patent Application Publication
(10) Pub. No.: US 2005/0173716 A1
(43) Pub. Date: Aug. 11, 2005

(54) Use of variable reflective material (varem)

(76) Inventors: Wilhelmus Gerardus Jacobus Van Helden, Schagen (NL); Herman Albert Zondag, Alkmaar (NL)

Correspondence Address: SUGHRUE MION, PLLC, 2100 PENNSYLVANIA AVENUE, N.W., SUITE 800, WASHINGTON, DC, 20037, US

(21) Appl. No.: 10/509,488

(22) PCT Filed: Mar. 27, 2003
(86) PCT No.: PCT/NL03/00233

(30) Foreign Application Priority Data
Mar. 29, 2002 (NL) 1020281

(51) Int. Cl. H01L 33/00

(52) U.S. Cl. 257/98

(57) ABSTRACT

The present invention relates to the use of a variable reflective material (VAREM), which material can be considered to be an assembly of thin layers of metal alloys, whose optical properties can be varied between reflecting and absorbing in the optical part of the spectrum. Another object of the present invention is to provide a device for converting solar energy into thermal energy and possibly electric energy, which device is provided with an optically variable coating, which can be controlled in such a manner that the transmissivity to sunlight thereof can be varied as needed.

The present invention relates to the use of a variable reflective material (VAREM), which material can be considered to be an assembly of thin layers of metal alloys, whose optical properties can be varied between reflecting and absorbing in the optical part of the spectrum.

The aforesaid variation is effected by changing the amount of hydrogen occluded in the crystal lattice of the alloy. Said amount of hydrogen may be varied, for example, by means of an external hydrogen pressure or an electric voltage or a temperature change when use is made of an additional layer structure (consisting of an ion conductor and a hydrogen storage layer) capable of injecting the required hydrogen ions into the switchable alloy.

Already in 1996 a team of Dutch research scientists discovered a group of materials that could be switched between a transparent phase and a reflecting phase by exposing them to hydrogen (see Nature 380, 231; (1996)). Said scientists discovered that thin films of particular metals, such as yttrium and lanthane, are capable of occluding hydrogen so as to form metallic hydride compounds, or, in the case of a larger amount of hydrogen, transparent compounds. They were capable of effecting the transformation between the transparent phase and the reflecting phase by pumping hydrogen over the films at varying pressures.

Japanese patent publication JP 59 004856 discloses a device which is capable of controlling the transparency of an EC layer, which makes it possible to make the rate of absorption of sunlight variable. The transparency of the EC layer is achieved by enclosing an electrolyte between two electrodes, and subsequently place a plate-like transparent member on one side of the electrodes, in such a manner that a space is formed, through which a liquid is passed, which liquid functions as a heat transferring medium. It is not clear between which phases the EC layer switches.

U.S. Pat. No. 5,457,564 discloses a combination of a photovoltaic cell and an electrochromic device. According to the construction that is shown therein, the electric output from photovoltaic cells will increase when the degree of colouration of the electrochromic device increases. Since said cells are positioned behind the electrochromic device, the incident light on the cells will have to pass through the electrochromic material. Also in this case an electrochromic layer is present, which switches between the transparent phase and the blocking phase, in which latter phase incident light on the PV cell is partially blocked in the embodiment as shown.

The article “Semi-transparent a-SiC:H solar cells for self-powered photovoltaic-electrochromic devices”, Bullock, J. N. et al, discloses a photovoltaic-electrochromic device as a “smart window” for active control of the heating and cooling processes, in which the illustrated stacking of the electrochromic layer and the PV cell is aimed at providing a transparent structure which controls the amount of light being transmitted independently. Said construction does not provide any information with regard to the absorption of solar energy and the subsequent discharge of the heat being generated in the most effective way that is possible.

Japanese patent publication JP 09 244072 relates to a device whose transmissivity is changed by incident light, which device comprises a layer of an electrochromic material. The structure being shown therein is transparent and the switching of the electrochromic layer is fully aimed at controlling the degree of transparency.

A problem that occurs when using photovoltaic/thermal solar panels, for example, is the fact that the temperature of such a panel may rise to very high levels, which high-temperature may cause damage to the panel. Such photovoltaic/thermal solar panels are known per se, for example from Dutch patent No 1005926 to the present applicant. The photovoltaic/thermal solar panel that is known therefrom comprises a panel-like carrier, which is provided with at least two substantially flat photovoltaic units, which are connected in series by an electrical conductor for receiving sunlight and converting said sunlight into an electric potential difference, in which each of the photovoltaic units can be manufactured separately and in which said photovoltaic units have a substantially elongated shape defined by two long sides and two short sides. In addition to that, solar panels are known in which the photovoltaic units are made up of series-connected solar cells consisting of slices of silicon material, which are arranged in spaced-apart relationship on a carrier plate. Some commercially available solar collectors are known to be provided with a spectrally selective coating having constant optical properties. It should furthermore be noted in this connection that the absorption coefficient for sunlight is high, in particular 70% or higher. In situations in which no heat is required of such a collector, the temperature may rise to very high levels, which will inevitably result in damage being caused to the solar panel. Also other photovoltaic techniques may be used, for example amorphous silicon, thin film techniques, such as CIS or Cd—Te, and microcrystalline silicon.

A first aspect of the present invention is thus to provide a device for converting solar energy into thermal energy and possibly electric energy, which device is provided with an optically variable coating, which is capable of reducing the aforesaid maximum temperatures to a considerable degree.

A second aspect of the present invention is to provide a device for converting solar energy into thermal energy and possibly electric energy, which device is provided with an optically variable coating, which can be controlled in such a manner that the transmissivity to sunlight thereof can be varied as needed.

A third aspect of the present invention is to provide a device for converting solar energy into thermal energy and possibly electric energy, which device is provided with an optically variable coating, as a result of which the life of the device can be prolonged significantly because of the fact that the occurrence of high temperature peaks is prevented.

The present invention as referred to in the introduction is characterized by the use of a variable reflective material (VAREM) in a device for converting solar energy into thermal energy and possibly electric energy, in which a layer of VAREM material is present between a sunlight-transmitting plate and a carrier plate.

The VAREM material that is used in the present invention is in particular suitable for switching between black absorbing and metallically reflecting in the optical portion of the spectrum, which characteristic is very advantageous with a view to achieving the aforesaid objectives of the present invention.

A suitable device is a device which comprises, in succession, a sunlight-transmitting plate and a heat-conducting substrate, which is spaced therefrom by some distance, as the carrier plate, in which substrate one or more channels are formed, in which channels a heat transferring medium is present, with the VAREM layer being present between the sunlight-transmitting plate and the substrate.

In such an embodiment the VAREM layer preferably abuts against the substrate, and in a special embodiment a layer of photovoltaic units is preferably present between the VAREM layer and the sunlight-transmitting plate, so that the incident sunlight will also be used for generating electric energy.

In such an embodiment the sunlight is not only converted into heat, but also into electric energy, as a result of a layer of said photovoltaic units being used, in which connection it is in particular desirable for the layer of photovoltaic units to abut against the VAREM layer.

Another special application of the present invention relates to a device which comprises, in succession, a first sunlight-transmitting plate, a second sunlight-transmitting plate and a thermally insulating carrier as the carrier plate, said plates being spaced a respective distance apart, in which the space formed by the second sunlight-transmitting plate and the thermally insulating carrier is divided into two separate subspaces by a layer of photovoltaic units, with a heat-transferring medium being present in each subspace and the VAREM layer being present in the subspace formed by the layer of photovoltaic units and the thermally insulating carrier.

In such a special embodiment, the VAREM layer preferably abuts against the thermally insulating layer, more particularly, the VAREM layer abuts against the layer of photovoltaic units.

According to another embodiment, the device comprises, in succession, a sunlight-transmitting plate and a thermally insulating carrier, which is spaced therefrom by some distance, as the carrier plate, in which a VAREM layer abutting against the carrier is positioned between the sunlight-transmitting plate and the carrier, on which VAREM layer a layer of photovoltaic units is present, with a heat-transferring medium being present in the space between the sunlight-transmitting plate and the layer of photovoltaic units.

In the aforesaid embodiments, the amount of sunlight that is converted into heat can be regulated by varying the degree of absorption of the VAREM layer. In the absorbing phase of the VAREM layer, the sunlight transmitted by the sunlight-transmitting plate is converted into heat, which heat is discharged by means of the heat-conducting substrate, in which one or more channels are present in which a heat-transferring medium, preferably water, is present. In the reflecting phase of the VAREM layer, the sunlight is reflected, as a result of which much less sunlight is converted into heat. In a normal operating situation it is thus possible to regulate the amount of heat being absorbed. The use of the VAREM layer in a reflecting phase reduces the amount of heat, therefore, resulting in significantly lower temperatures, so that the VAREM layer protects the panel against undesirably high temperatures. If the photovoltaic units are transparent, which means that no reflecting electrical contact is present on the rear side thereof, the sunlight that is reflected in the reflecting phase of the VAREM layer will be passed through the layer of photovoltaic units once again, which increases the electric efficiency in comparison with the embodiment in which the VAREM layer is in the absorbing phase. In the situation of non-transparent photovoltaic units, only regulation of sunlight that passes between the photovoltaic units will take place.

In the embodiment that does not comprise a layer of photovoltaic units, the danger of high temperatures is in principle less manifest as in an embodiment in which the layer of photovoltaic units is present; in practice, however, it is desirable to regulate the amount of heat obtained from incident sunrays. For example, if the device is provided with a coating that transmits infrared radiation, the VAREM layer can be used in particular when the device is to be used as a cooling device in a dark situation, with the VAREM layer being in the absorbing phase. The heat-conducting substrate will cool down if the radiation temperature from the atmosphere is lower than the surface temperature of the VAREM layer, in which situation the heat can be given off to the atmosphere through radiation. In specific embodiments it is thus desirable for the sunlight-transmitting plate to transmit infrared radiation as well.

Another application of a variable reflective material (VAREM) in a device for converting solar energy into thermal energy is a so-called Trombe wall. A Trombe wall is a wall which is disposed just behind a window and which is generally provided with a dark surface layer. The sunrays passing through the window during the daytime are absorbed by the wall, causing it to heat up. The thickness of the Trombe wall is such that the absorbed heat has penetrated through the wall towards dark, so that it can subsequently heat the space behind the wall. Up to now, such a system has been completely passive, which means that the wall may become too hot after a few days in full sunlight, which is undesirable and which is often prevented in practice by placing external sunshades. If the Trombe wall is provided with a VAREM layer, it is thus possible to regulate this system in an effective manner, for example by switching the VAREM layer to its reflecting phase when heat is not needed (any more).

According to a special embodiment, the VAREM layer is built up of, in succession, a metal alloy, a solid electrolyte and an electrode, which VAREM layer is enveloped by a closed hydrogen atmosphere, in which the hydrogen concentration of the metal alloy is controlled by applying an electric voltage between the electrode and the metal alloy. In addition to that it is possible for the VAREM layer to be built up of, in succession, a metal alloy, a solid electrolyte, a storage electrode, a top electrode, and a hydrogen-impermeable layer, in which the hydrogen concentration of the metal alloy is controlled by applying an electric voltage between the electrode and the metal alloy.

In the latter embodiment, it is moreover possible to substitute the top electrode and the storage electrode for one layer which is capable of simple absorption of hydrogen. This applies in particular to transition metals, such as V, Nb, Ta and Pd.

The hydrogen concentration (and thus the optical phase) of the VAREM layer is driven by applying an electric voltage between a hydrogen-permeable electrode (for example Pd) and the metal alloy. The solid electrolyte has a dual function in this regard, it enables the transportation of H-ions/protons and it blocks the transportation of electrons.

The metal alloy is selected from an alloy of e.g. Mg and a transition metal, such as Ni, Co, Fe.

A suitable solid electrolyte is e.g. ZrO₂ and Y:CaF₂ (yttrium-doped calcium).

The storage electrode in particular consists of, for example, WO₃.

The present invention will be explained in more detail hereinafter by means of a number of examples, in which it should be noted, however, that the present invention is by no means limited to such examples.

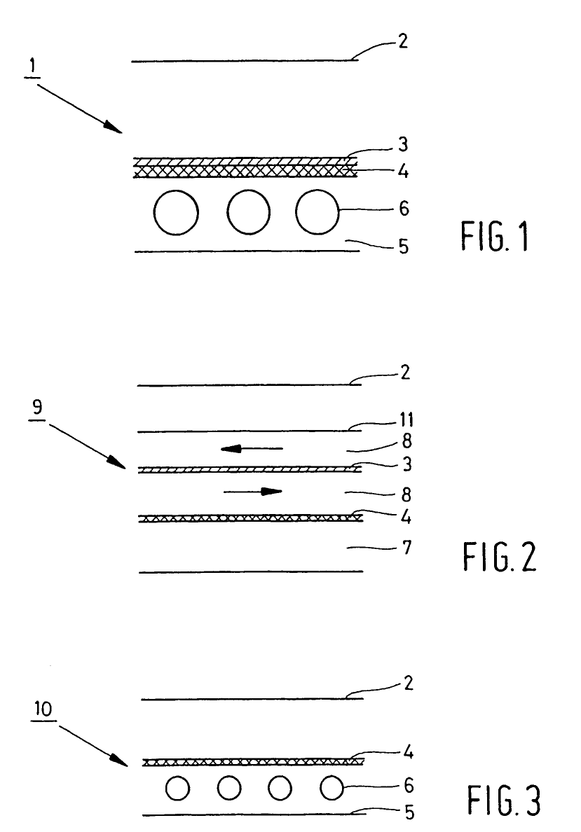

FIG. 1 shows an embodiment of a VAREM layer in a device provided with a layer of transparent photovoltaic units.

FIG. 2 shows a special embodiment of a VAREM layer in a device provided with photovoltaic units.

FIG. 3 shows an embodiment of a thermal collector in which a VAREM layer is present.

In FIG. 1, a device for converting solar energy into both thermal energy and electrical energy is schematically shown. The incident sunlight passes through the sunlight-transmitting plate 2 and strikes on a layer of photovoltaic units 3, which layer 3 is transparent in this embodiment. Present under said layer of photovoltaic units 3 is the VAREM layer 4, which VAREM layer 4 abuts against a heat-conducting substrate 5, in which channels 6 are present for the passage therethrough of a heat-transmitting medium, preferably water. The amount of sunlight that is usefully used for heating the heat-transmitting medium is regulated by switching the VAREM layer 4 between an absorbing phase and a reflecting phase. Since the layer of photovoltaic units 3 is transparent in this embodiment, the electric efficiency will increase if the incident sunlight is passed through the layer of photovoltaic units 3 once again as a result of the VAREM layer 4 being switched to a reflecting phase. In the case of a non-transparent layer of photovoltaic units, only regulation of sunlight that passes between the photovoltaic units will take place.

FIG. 2 schematically shows the structure of a device 9 in which solar energy is converted into both thermal energy and electrical energy. The sunlight enters via a first sunlight-transmitting plate 2 and subsequently strikes on a second sunlight-transmitting plate 11, which is disposed some distance away therefrom. A thermally insulating carrier 7 is disposed a particular distance away from the second, sunlight-transmitting plate 11, which thermally insulating carrier 7 is provided with a VAREM layer 4 on one side. The space between the VAREM layer 4 and the second sunlight-transmitting plate 11 is divided into two separate subspaces 8 by a layer of photovoltaic units 3, in which subspace thermal energy is transferred to the water once again. A heat-transferring medium, for example water, is carried into the subspace 8 adjacent to the second light-transmitting plate 11, which heat-transferring medium is heated by the incident sunlight and which is returned via the subspace 8 formed by the space enclosed by the VAREM layer 4 and the layer of photovoltaic units 3, in which subspace thermal energy is transferred to the water once again. According to such an embodiment, the incident sunlight is converted into electrical energy, as a result of the presence of the layer of photovoltaic units 3, and also into thermal energy, which is given off to the water that forms the heat-transferring medium. According to an alternative embodiment (not shown), the layer of photovoltaic units 3 may abuts against the VAREM layer 4, so that only one subspace 8 is present, which subspace 8 forms a channel for the heat-transferring medium, in particular water.

FIG. 3 finally shows a device 10 for converting solar energy only into thermal energy, in which the sunlight strikes on a VAREM layer 4 via a sunlight-transmitting plate 2, which VAREM layer 4 abuts against a heat-conducting substrate 5, in which channels 6 are present, through which a heat-transferring medium, for example water, is passed. The amount of heat being transferred to the heat-transferring medium that is present in the channels 6 can be regulated by switching the VAREM layer 4 between a transparent phase and a reflecting phase.

1. The use of a variable reflective material (VAREM) in a device (1, 9, 10) for converting solar energy into thermal energy and possibly electric energy, wherein a layer of VAREM material (4) is present between a sunlight-transmitting plate (2, 11) and a carrier plate (5, 7).

2. The use according to claim 1, characterized in that the device comprises a sunlight-transmitting plate (2) and a heat-conducting substrate (5), which is spaced therefrom by some distance, as the carrier plate, in which substrate (5) one or more channels (6) are formed, in which channels (6) a heat transferring medium is present, with the VAREM layer (4) being present between the sunlight-transmitting plate (2) and the substrate (5).

3. The use according to claim 2, characterized in that the VAREM layer (4) abuts against the substrate (5).

4. The use according to claim 2, characterized in that a layer of photovoltaic units (3) is present between the VAREM layer (4) and the sunlight-transmitting plate (2).

5. The use according to claim 4, characterized in that the layer of photovoltaic units (3) abuts against the VAREM layer (4).

6. The use according to claim 1, characterized in that the device comprises a first sunlight-transmitting plate (2), a second sunlight-transmitting plate (11) and a thermally insulating carrier (7) as the carrier plate, said plates being spaced a respective distance apart, wherein the space (8) formed by the second sunlight-transmitting plate (11) and the thermally insulating carrier (7) is divided into two separate subspaces by a layer of photovoltaic units (3), with a heat transferring medium being present in each subspace and the VAREM layer (4) being present in the subspace formed by the layer of photovoltaic units (3) and the thermally insulating carrier (7).

7. The use according to claim 6, characterized in that the VAREM layer (4) abuts against the thermally insulating layer (7).

8. The use according to claim 6, characterized in that the VAREM layer (4) abuts against the layer of photovoltaic units (3).

9. The use according to claim 1, characterized in that the device comprises a sunlight-transmitting plate (2) and a thermally insulating carrier (7), which is spaced therefrom by some distance, as the carrier plate, wherein a VAREM layer (4) abutting against the carrier (7) is positioned between said plate (2) and said carrier (7), on which VAREM layer (4) a layer of photovoltaic units (3) is present, with a heat-transferring medium being present in the space between the sunlight transmitting plate (2) and the layer of photovoltaic units (3).

10. The use according to claim 2, characterized in that the sunlight-transmitting plate (2, 11) also transmits infrared radiation.

11. The use according to claim 1, characterized in that the VAREM layer (4) is present on a Trombe wall.

12. The use according to claim 1, characterized in that the VAREM layer (4) is built up of, in succession, a metal alloy, a solid electrolyte and an electrode, which VAREM layer (4) is enveloped by a closed hydrogen atmosphere, wherein the hydrogen concentration of the metal alloy is controlled by applying an electric voltage between the electrode and the metal alloy.

13. The use according to claim 1, characterized in that the VAREM layer (4) is built up of, in succession, a metal alloy, a solid electrolyte, a storage electrode, a top electrode, and a hydrogen-impermeable layer, wherein the hydrogen concentration of the metal alloy is controlled by applying an electric voltage between the electrode and the metal alloy.

14. The use according to claim 12, characterized in that said electric voltage is generated by using a photocell.

15. The use according to claim 12, characterized in that the metal alloy is selected from an alloy of Mg and a transition metal, such as Ni, Co, Fe.

16. The use according to claim 12, characterized in that the solid electrolyte is selected from the group consisting of Zr0₂ and Y:CaF₂.

17. The use according to claim 13, characterized in that the storage electrode consists of W0₃.

18. The use according to claim 13, characterized in that either ZrO₂ or yttrium oxide is used for the hydrogen-impermeable layer.

19. The use according to claim 13, characterized in that the storage electrode and the top electrode form one unit obtained from transition metals such as V, Nb, Ta and Pd.
